(19) United States
(12) Patent Application Publication
(10) Pub. No.: US 2023/0284469 A1
(43) Pub. Date: Sep. 7, 2023

(54) LIGHT-EMITTING ELEMENT, AND LIGHT-EMITTING DEVICE

(71) Applicant: SHARP KABUSHIKI KAISHA, Sakai City, Osaka (JP)

(72) Inventors: Keisuke KITANO, Sakai City, Osaka (JP); Masaki YAMAMOTO, Sakai City, Osaka (JP)

(21) Appl. No.: 18/015,453

(22) PCT Filed: Aug. 4, 2020
(86) PCT No.: PCT/JP2020/029728

§ 371 Date: Jan. 10, 2023

(51) Int. Cl. H10K 50/115; H10K 50/858

(52) U.S. Cl. CPC H10K 50/115; H10K 50/858

(57) ABSTRACT

A light-emitting element includes: a first light-emitting layer containing quantum dots and emitting a first light including a first peak wavelength; a second light-emitting layer containing quantum dots and emitting a second light including a second peak wavelength greater than the first peak wavelength; a substrate on which the first light-emitting layer and the second light-emitting layer are arranged side-by-side in a first direction; and a first bank provided on the substrate and dividing the first light-emitting layer from the second light-emitting layer. The first bank is transparent to the first light.

### TECHNICAL FIELD

The present invention relates to a light-emitting element and a light-emitting device.

### BACKGROUND ART

Patent Document 1 discloses a light-emitting device including: a light-emitting layer provided on a substrate; and a bank dividing the light-emitting layer on the substrate so that each of the divided light-emitting layers corresponds one of sub-pixels. Patent Document 1 discloses a configuration in which, on the bank, a reflective unit is provided in contact with an organic light-emitting layer.

### CITATION LIST

### Patent Literature

Patent Document 1: Japanese Unexamined Patent Application Publication No. 2020-004724

### SUMMARY OF INVENTION

### Technical Problem

However, Patent Document 1 described above has a problem; that is, of the light emitted from the light-emitting layer, some of the light propagates in an in-plane direction of a light-emitting surface of the light-emitting device. The propagating light is reflected in the organic light-emitting layer and on an interface of an electrode provided on the organic light-emitting layer, and fails to exit outside.

An object of the present disclosure is to provide a light-emitting element and a light-emitting device capable of effectively using light propagating in an in-plane direction of a light-emitting surface of the light-emitting device.

### Solution to Problem

A light-emitting element according to an aspect of the present disclosure includes: a first light-emitting layer containing first quantum dots and configured to emit a first light including a first peak wavelength; a second light-emitting layer containing second quantum dots and configured to emit a second light including a second peak wavelength greater than the first peak wavelength; a substrate having a surface on which the first light-emitting layer and the second light-emitting layer are arranged side-by-side in a first direction; and a first bank provided on the substrate and dividing the first light-emitting layer from the second light-emitting layer, wherein the first bank is transparent to the first light traveling from the first light-emitting layer toward the second light-emitting layer.

Moreover, a light-emitting element according to an aspect of the present disclosure includes: a plurality of first light-emitting layers each containing first quantum dots and configured to emit a first light including a first peak wavelength; a substrate on which the plurality of first light-emitting layers are arranged in line; and a bank provided on the substrate and dividing two of the first light-emitting layers arranged side-by-side, wherein, between the two first light-emitting layers, the bank is transparent to the first light emitted from each of the two first light-emitting layers.

Furthermore, a light-emitting device according to an aspect of the present disclosure includes: a thin-film transistor; and the light-emitting element electrically connected to the thin-film transistor. This light-emitting element includes: a first light-emitting layer containing first quantum dots and configured to emit a first light including a first peak wavelength; a second light-emitting layer containing second quantum dots and configured to emit a second light including a second peak wavelength greater than the first peak wavelength; a substrate having a surface on which the first light-emitting layer and the second light-emitting layer are arranged side-by-side in a first direction; and a first bank provided on the substrate and dividing the first light-emitting layer from the second light-emitting layer, wherein the first bank is transparent to the first light traveling from the first light-emitting layer toward the second light-emitting layer.

### BRIEF DESCRIPTION OF DRAWINGS

FIG. 1 is a schematic plan view of an essential configuration of a light-emitting device according to an embodiment.

FIG. 2 is a cross-sectional view of the light-emitting device illustrated in FIG. 1, taken from line II-II of FIG. 1.

FIG. 3 is a schematic plan view of an essential configuration of the light-emitting device according to a second modification of the embodiment.

FIG. 4 is a cross-sectional view of the light-emitting device illustrated in FIG. 3, taken from line IV-IV of FIG. 3.

FIG. 5 is a schematic plan view of an essential configuration of the light-emitting device according to a third modification of the embodiment.

FIG. 6 is a cross-sectional view of the light-emitting device 1 illustrated in FIG. 5, taken from line IV-IV of FIG. 5.

FIG. 7 is a cross-sectional view of the light-emitting device 1 illustrated in FIG. 5, taken from line VII-VII of FIG. 5.

FIG. 8 is a cross-sectional view of an essential configuration of the light-emitting device according to a fourth modification of the embodiment.

### DESCRIPTION OF EMBODIMENT

Described below is an exemplary embodiment of the present disclosure, with reference to the drawings. Note that, hereinafter, the term “above” denotes a direction from an array substrate 2 (a substrate) toward a light-emitting element 3 of a light-emitting device 1, and the term “below” denotes the opposite direction of the term “above”. Moreover, like reference signs designate identical constituent features throughout the drawings. Such constituent features will not be repeatedly elaborated upon.

### EMBODIMENT

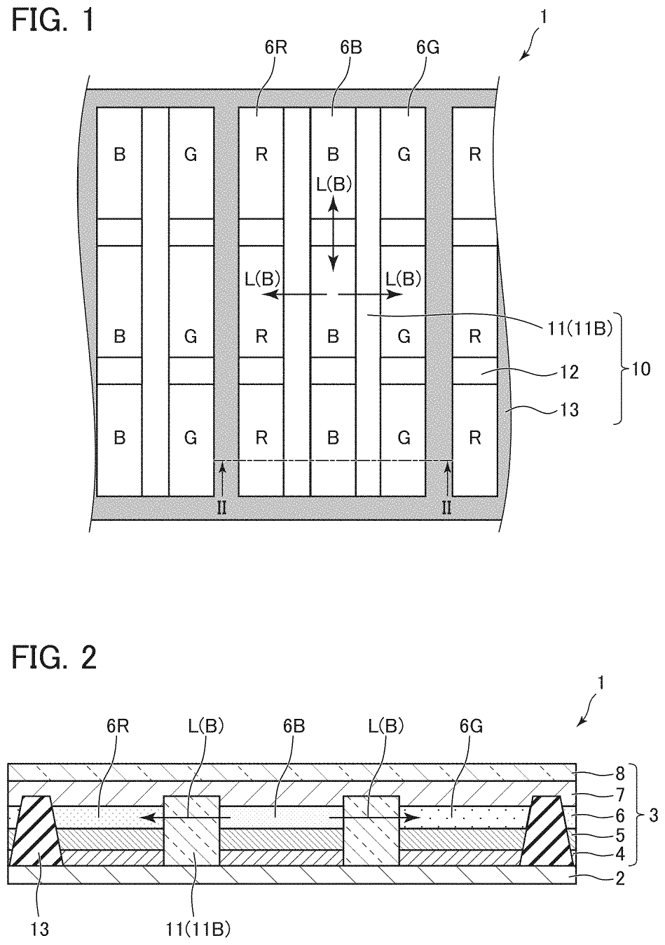

FIG. 1 is a schematic plan view of an essential configuration of the light-emitting device 1 according to the embodiment. FIG. 2 is a cross-sectional view of the light-emitting device 1 illustrated in FIG. 1, taken from line II-II of FIG. 1. The light-emitting device 1 can be used for, for example, a display of such a device as a TV or a smartphone. Note that, in FIGS. 1 and 2, light L passing through a bank 10 is indicated by arrows.

As illustrated in FIGS. 1 and 2, the light-emitting device 1 includes the light-emitting element 3 having a light-emitting layer 6. The light-emitting layer 6 contains quantum dots that emit light whose peak wavelength is in a visible light range. The light-emitting layer 6 includes: a plurality of blue light-emitting layers 6B containing quantum dots that emit a blue light including a blue peak wavelength; a plurality of green light-emitting layers 6G containing quantum dots that emit a green light L (G) including a green peak wavelength; and a plurality of red light-emitting layers 6R containing quantum dots that emit a red light L (R) including a third quantum red peak wavelength. Note that the sizes of the quantum dots are larger in the order of the quantum dots contained in each of the plurality of blue light-emitting layers 6B, the quantum dots contained in each of the plurality of green light-emitting layers 6G, and the quantum dots contained in each of the plurality of red light-emitting layers 6R. In this Description, as to a relationship between the quantum dots contained in each of the plurality of blue light-emitting layers 6B, and the quantum dots contained in each of either the plurality of green light-emitting layers 6G or the plurality of red light-emitting layers 6R, the former quantum dots are first quantum dots, and the latter quantum dots are second quantum dots. Moreover, as to a relationship between the quantum dots contained in each of the plurality of green light-emitting layers 6G, and the quantum dots contained in each of the plurality of red light-emitting layers 6R, the former quantum dots are the first quantum dots, and the latter quantum dots are the second quantum dots. Furthermore, in this Description, if the blue light-emitting layers 6B, the green light-emitting layers 6G, and the red light-emitting layers 6R do not have to be distinguished from one another, these layers are simply referred to as the light-emitting layers 6. Note that the blue light L (B) is light including the peak wavelength in a wavelength region of 400 nm or more and 500 nm or less. Moreover, the green light L (G) is light including the peak wavelength in a wavelength region of more than 500 nm and 600 nm or less. Furthermore, the red light L (R) is light including the peak wavelength in a wavelength region of more than 600 nm and 780 nm or less. In FIG. 1, the blue light-emitting layer 6B, the green light-emitting layer 6G, and the red light-emitting layer 6R are respectively denoted by the signs “B”, “G”, and “R”.

The plurality of blue light-emitting layers 6B, the plurality of green light-emitting layers 6G, and the plurality of red light-emitting layers 6R are arranged on a surface of, and in an in-plane direction of, the array substrate 2. Thus, in the light-emitting device 1 according to the embodiment, the plurality of blue light-emitting layers 6B, green light-emitting layers 6G, and red light-emitting layers 6R form a light-emitting surface in parallel with the in-plane direction of the array substrate 2.

Specifically, in FIG. 1, a horizontal direction in the drawing is a horizontal-axis direction (a first direction) of the light-emitting device 1, and a direction perpendicular to this horizontal-axis direction is a vertical-axis direction (a second direction) of the light-emitting device 1. Here, the blue light-emitting layers 6B, the green light-emitting layers 6G, and the red light-emitting layers 6R are alternately arranged in the stated order in the horizontal-axis direction. Moreover, the plurality of blue light-emitting layers 6B, the plurality of the green light-emitting layers 6G, and the plurality of red light-emitting layers 6R are arranged in respective groups in the vertical-axis direction. Note that, in the light-emitting device 1 according to the embodiment, each of the plurality of blue light-emitting layers 6B, green light-emitting layers 6G, and red light-emitting layers 6R corresponds to one of sub-pixels in the light-emitting device 1. Each of the light-emitting layers is divided by the bank 10.

Light-Emitting Device

Described below with reference to FIG. 2 is a detailed configuration of the light-emitting device 1 according to the embodiment. The light-emitting device 1 includes: the array substrate 2; and the light-emitting element 3. The array substrate 2 is a glass substrate in which not-shown thin-film transistors (TFTs) are formed for driving the light-emitting element 3. Above the array substrate 2, the layers of the light-emitting element 3 are stacked on top of another.

The light-emitting element 3 includes: an anode 4; a hole-transport layer 5; a light-emitting layer 6; an electron-transport layer 7; and a cathode 8. In the light-emitting device 1 according to the embodiment, the anode 4, the hole-transport layer 5, the light-emitting layer 6, the electron-transport layer 7, and the cathode 8 are stacked on top of another in the stated order from below upward above the array substrate 2.

The anode 4 is formed on the array substrate 2, and electrically connected to a TFT of the array substrate 2. The anode 4 is a reflective substrate containing: a metal including Al, Cu, Au, or Ag highly reflective to visible light; and a transparent material including ITO, IZO, ZnO, AZO, or BZO. The metal and the transparent material are stacked on top of another above the array substrate 2. The anode 4 can be formed by, for example, sputtering or vapor deposition.

The hole-transport layer 5 transports holes injected from the anode 4 further into the light-emitting layer 6. The hole-transport layer 5 is formed on, and electrically connected to, the anode 4. Examples of the hole-transport layer 5 include an arylamine derivative, an anthracene derivative, a carbazole derivative, a thiophene derivative, a fluorene derivative, a distyrylbenzene derivative, a spiro compound, and metal oxide. The hole-transport layer 5 can be formed by such a technique as, for example, vapor deposition, printing, ink-jet printing, spin coating, casting, dipping, bar coating, blade coating, roll coating, gravure coating, flexographic printing, spray coating, photolithography, or self-assembly (layer-by-layer and self-assembled monolayer). Note that the hole-transport layer 5 may be formed of nanoparticles, crystals, polycrystals, or an amorphous solid.

Moreover, between the hole-transport layer 5 and the anode 4, a not-shown hole-injection layer may be provided to promote injection of the holes from the anode 4.

The light-emitting layer 6 is provided between the anode 4 and the cathode 8. More specifically, the light-emitting layer 6 is provided between the hole-transport layer 5 and the electron-transport layer 7. The light-emitting layer 6 contains quantum dots (semiconductor nanoparticles) in the form of one or more layers stacked on top of another. The light-emitting layer 6 can be formed of a fluid disperse containing such a solvent as hexane or toluene into which the quantum dots are dispersed. The light-emitting layer 6 can be formed by spin-coating or ink-jet printing. In the fluid disperse, such a dispersant as thiol or amine may be mixed.

The quantum dots, which have a valence band level and conduction band level, are a light-emitting material that emits light by recombination of the hole at the valence band level and the electrons at the conduction band level. The light emitted from the quantum dots has a narrow spectrum because of the quantum confinement effect, so that the emitted light can be relatively deep in chromaticity.

Each of the quantum dots is a semiconductor nanoparticle having a core/shell structure including: a core made of CdSe; and a shell made of ZnS. Other than that, the quantum dot may have such a core/shell structure as CdSe/CdS, InP/ZnS, ZnSe/Zn, or CIGS/ZnS. Moreover, the shell has an outer periphery portion to which a ligand is coordinated. The ligand is made of, for example, such an organic substance as thiol or amine.

The quantum dots have a particle size of approximately 3 nm to 15 nm. A wavelength of light emitted from the quantum dots can be controlled by the particle size of the quantum dots. Hence, by controlling the particle size of the quantum dots, a wavelength of light emitted from the light-emitting device 1 can be controlled.

The electron-transport layer 7 is provided on the light-emitting layer 6. The electron-transport layer 7 is a transparent conductive film to transport the electrons injected from the cathode 8 into the light-emitting layer 6. The electron-transport layer 7 may function to keep the holes from being transported to the cathode 8 (a hole-blocking function). Examples of the electron-transport layer 7 include: oxadiazoles, triazoles, phenanthrolines, a silole derivative, a cyclopentadiene derivative, an aluminum complex, and metal oxide. The electron-injection layer can be formed by such a technique as, for example, vapor deposition, printing, ink-jet printing, spin coating, casting, dipping, bar coating, blade coating, roll coating, gravure coating, flexographic printing, spray coating, photolithography, or self-assembly (layer-by-layer and self-assembled monolayer).

Moreover, between the electron-transport layer 7 and the cathode 8, a not-shown electron-injection layer may be provided to promote injection of the electrons from the cathode 8.

The cathode 8 is formed on, and electrically connected to, the electron-transport layer 7. The cathode 8 can be formed of either a thin metal film transparent to light, or a transparent material. Examples of the metal forming the cathode 8 include Al, Ag, and Mg. Moreover, examples of the transparent material forming the cathode 8 include ITO, IZO, ZnO, AZO, and BZO. The cathode 8 can be formed by, for example, sputtering or vapor deposition.

In the light-emitting device 1 having the above configuration, the holes injected from the anode 4 and the electrons injected from the cathode 8 are transported respectively through the hole-transport layer 5 and the electron-transport layer 7 to the light-emitting layer 6. Then, the holes and the electrons transported to the light-emitting layer 6 recombine together in quantum dots 61, and an exciton occurs. When the exciton transfers from an excited state back to a ground state, the quantum dots 61 emit light.

Note that FIG. 2 shows, as an example, the light-emitting device 1 of a top-emission type that emits light from the light-emitting layer 6 and releases the light across from the array substrate 2 (upwards in FIG. 2). However, the light-emitting device 1 may be of a bottom-emission type that releases the light from toward the array substrate 2 (downwards in FIG. 2). If the light-emitting device 1 is of the bottom-emission type, the cathode 8 is a reflective electrode and the anode 4 is a transparent electrode. Moreover, the hole-transport layer 5 is a transparent conductive film.

Furthermore, the light-emitting device 1 according to the embodiment includes: the anode 4; the hole-transport layer 5; the light-emitting layer 6; the electron-transport layer 7; and the cathode 8, all of which are stacked on top of another in the stated order from below upward above the array substrate 2. However, the light-emitting device 1 may also be of an inverted structure; that is, the light-emitting device 1 include: the cathode 8; the electron-transport layer 7; the light-emitting layer 6; the hole-transport layer 5; and the anode 4, all of which are stacked on top of another in the stated order from below upward above the array substrate 2.

The light-emitting device 1 according to the embodiment is provided with the bank 10 on the array substrate 2. The bank 10 divides each of the blue light-emitting layers 6B, each of the green light-emitting layers 6G, and each of the red light-emitting layers 6R. The bank 10 includes: a first bank region 11 (a first bank); a second bank region 12 (a second bank); and a third bank region 13. Each of the bank regions is described below.

First Bank Region

The first bank region 11 is a region to divide the light-emitting layers 6 arranged side-by-side above the array substrate 2 and emitting light in different peak wavelengths. Of the light rays emitted from each of the light-emitting layers 6 arranged side-by-side, the first bank region 11 is transparent to a light ray having a shorter peak wavelength (a first light), and non-transparent to a light ray having a longer peak wavelength (a second light).

In the light-emitting device 1 illustrated in FIGS. 1 and 2, the first bank region 11 divides a blue light-emitting layer 6B (a first light-emitting layer) from a green light-emitting layer 6G (a second light-emitting layer) arranged side-by-side above the array substrate 2. The first bank region 11 also divides the blue light-emitting layer 6B from a red light-emitting layer 6R (the second light-emitting layer). Then, the first bank region 11 is transparent to a blue light L (B). The blue light L (B) has a blue peak wavelength and travels from the blue light-emitting layer 6B toward the green light-emitting layer 6G. Note that, in the first bank region 11, a region transparent to the blue light L (B) is referred to as a first bank region 11B. This first bank region 11B can be made of such a material as acrylic resin, epoxy resin, or polyimide, all of which are transparent to the blue light L (B).

That is, the blue light L (B), which propagates in the in-plane direction of the light-emitting surface of the light-emitting element 3, is partially reflected because of a difference in refractive index on an interface between the cathode 8; that is, a transparent electrode provided above the blue light-emitting layer 6B, and a layer (i.e. air if no layer is formed) formed above the cathode 8. Hence, the reflected light is not released outside. Hence, as to the light-emitting device 1 according to the embodiment, the blue light L (B) not released outside is allowed to pass through the first bank region 11B and is propagated to the red light-emitting layer 6R and the green light-emitting layer 6G arranged next to the blue light-emitting layer 6B.

Here, the red light-emitting layer 6R absorbs light whose peak wavelength is equal to the peak wavelength of red or below, and the green light-emitting layer 6G absorbs light whose peak wavelength is equal to the peak wavelength of green or below. Hence, the light-emitting device 1 emits light by photoluminescence (PL).

Thus, the light-emitting device 1 allows the red light-emitting layer 6R and the green light-emitting layer 6G to: absorb the blue light L (B) emitted from the blue light-emitting layer 6B; and emit light. Thanks to such a feature, the light-emitting device 1 can reduce a voltage to be applied to the light-emitting layers 6 for emitting the red light L (R) and the green light L (G).

For example, a light-emitting device emits a blue light having a luminance of 1000 cd/m² (0.9 μW/mm²). Moreover, the light-emitting device fails to emit outside the blue light propagating in the in-plane direction of the light-emitting surface. In other words, as to the light-emitting device, a rate of the blue light to be emitted outside is determined in accordance with a rate of light totally reflected on an interface between the light-emitting layer and a layer above the light-emitting layer. Because of such a configuration of the light-emitting device, 20% of the emitted blue light is released out of the light-emitting element 3, and 80% of the emitted blue light stays inside the light-emitting element 3. That is, the light having a luminance of 3.6 μW/mm² stays inside the light-emitting element 3.

Here, the green light-emitting layer 6G next to the blue light-emitting layer 6B absorbs and emits the blue light L (B) that stays inside the light-emitting element 3. The light-emitting device 1 is expected to exhibit an advantageous effect of reducing a voltage by 0.1 V with respect to light emitted at a luminance of 5 μW/mm². If an optical density of the first bank region 11B is 0, the voltage to be applied to the green light-emitting layer 6G to emit a green light can be reduced by 0.1 V.

Moreover, the reduced amount of the voltage depends on the optical density of the first bank region 11B. For example, if the optical density of the first bank region 11B is 1, the voltage to be applied can be reduced by 0.01 V. Moreover, if the optical density of the first bank region 11B is 2, the voltage to be applied can be reduced by 0.001 V.

Hence, preferably, the optical density of the first bank region 11B is, in particular, 1 or less. If the optical density of the first bank region 11B is 1 or less, the voltage can be reduced by 0.01 V or more. Such a feature makes it possible to effectively reduce the voltage of the light-emitting device 1.

Moreover, in order to reduce reflection on an interface between the first bank region 11B and the blue light-emitting layer 6B, a refractive index of the first bank region 11 is the same as, or close to, a refractive index of the blue light-emitting layer 6B. In particular, when the blue light L (B) is lost by the reflection on the interface between the first bank region 11B and the blue light-emitting layer 6B because of a difference in refractive index between the first bank region 11B and the blue light-emitting layer 6B, the rate of the loss is reduced to less than 1%. That is, a refractive index of the blue light-emitting layer 6B is n_{QD}, and a refractive index of the first bank region 11B is n. Here, an expression (1) below represents a condition in which a reflectance (normal incidence) is less than 1% of light incident from the blue light-emitting layer 6B having the refractive index n_{QD} to the first bank region 11B having the refractive index n.

(n_{QD}−n)²/(n_{QD}+n)²<0.01 (1)

Hence, the refractive index of the blue light-emitting layer 6B and the refractive index of the first bank region 11B are set to satisfy the relationship of an expression (2) below derived from the above expression (1).

n_{QD}×9/11<n<n_{QD}×11/9 (2)

Second Bank Region

The second bank region 12 is a region to divide a plurality of light-emitting layers 6 arranged side-by-side and emitting light rays in the same peak wavelength and the same color. In the light-emitting device 1 illustrated in FIGS. 1 and 2, the second bank region 12 is provided between two of the blue light-emitting layers 6B arranged side-by-side in the vertical-axis direction. Then, of the blue lights L (B) emitted from the two blue light-emitting layers 6B arranged side-by-side, the second bank region 12 is transparent to a blue light L (B) incident to each of the blue light-emitting layers 6B arranged side-by-side.

Hence, the light-emitting device 1 according to the embodiment allows the blue light-emitting layers 6B to: absorb light having a wavelength shorter than the blue peak wavelength included in the blue light L (B) passing through the second bank region 12; and emit light by PL.

Moreover, in the light-emitting device 1 illustrated in FIGS. 1 and 2, the second bank region 12 is provided also between two of the green light-emitting layers 6G arranged side-by-side in the vertical-axis direction. Then, of the green lights L (G) including a green peak wavelength and emitted from the two green light-emitting layers 6G arranged side-by-side, the second bank region 12 is transparent to a green light L (G) incident to each of the neighboring green light-emitting layers 6G.

Hence, the light-emitting device 1 according to the embodiment allows the green light-emitting layers 6G to: absorb light having a wavelength shorter than the green peak wavelength included in the green light L (G) passing through the second bank region 12; and emit light by PL.

Moreover, in the light-emitting device 1 illustrated in FIGS. 1 and 2, the second bank region 12 is provided also between two of the red light-emitting layers 6R arranged side-by-side in the vertical-axis direction. Then, of the red lights L (R) including a red peak wavelength and emitted from the two red light-emitting layers 6R arranged side-by-side, the second bank region 12 is transparent to a red light L (R) incident to each of the neighboring red light-emitting layers 6R. Hence, the light-emitting device 1 according to the embodiment allows the red light-emitting layers 6R to: absorb light having a wavelength shorter than the red peak wavelength included in the red light L (R) passing through the second bank region 12; and emit the absorbed light by PL.

Thus, as to the light-emitting device 1 according to this embodiment, when light is emitted from the two neighboring blue light-emitting layers 6B, the two neighboring green light-emitting layers 6G, and the two neighboring red light-emitting layer 6R emit light, the light-emitting device 1 can reduce a voltage to be applied to each of the light-emitting layers 6.

Note that the second bank region 12 can be made of a transparent material transparent to light so that the light emitted from the two neighboring blue light-emitting layers 6B, the two neighboring green light-emitting layers 6G, and the two neighboring red light-emitting layers 6R can pass through the second bank region 12. This transparent material is preferably at least one resin selected from the group consisting of, for example, acrylic polymer, polysiloxane, and polyimide.

Third Bank Region

Moreover, the third bank region 13 is the remaining region except the first bank region 11 and the second bank region 12 described above. In the light-emitting device 1 according to the embodiment, the third bank region 13 is a region to divide a green light-emitting layer 6G from a red light-emitting layer 6R both of which are arranged side-by-side above the array substrate 2. Furthermore, the third bank region 13 is a region to surround a blue light-emitting layer 6B, the green light-emitting layer 6G, and the red light-emitting layer 6R along an outer periphery of the array substrate 2.

Of the light rays emitted from the green light-emitting layer 6G and the red light-emitting layer 6R, the third bank region 13 reflects outside, in particular, a light ray propagating in the in-plane direction of the light-emitting surface and kept from traveling outside. Specifically, the third bank region 13 has side faces each in contact with one of the green light-emitting layer 6G and the red light-emitting layer 6R. The side faces are angled in the vertical direction. That is, as illustrated in FIG. 2, a cross-section of the third bank region 13 is narrower from array substrate 2 upward; that is, the cross-section is tapered. Then, the third bank region 13 is either significantly hardly transparent to light or not transparent to light, compared with the other bank regions. The third bank region 13 is made of a material that reflects most of, or all of, the light emitted from the light-emitting layers 6. For example, the third bank region 13 can be made of such a material as black resist.

As can be seen, the third bank region 13 reflects light propagating in the in-plane direction of the light-emitting surface so that the propagating light is released outside. Hence, the light-emitting device 1 can effectively use the light emitted from each of the green light-emitting layer 6G and the red light-emitting layer 6R.

Note that, in the above configuration, the blue light L (B) emitted from the blue light-emitting layer 6B is propagated through the first bank region 11B to each of: the green light-emitting layer 6G disposed next to the blue light-emitting layer 6B; and the red light-emitting layer 6R disposed next to the blue light-emitting layer. However, the light-emitting device 1 of the present disclosure shall not be limited to such a configuration. Alternatively, the light-emitting device 1 may be configured as follows. That is, the first bank region 11 may be a region provided between a green light-emitting layer 6G and a red light-emitting layer 6R arranged side-by-side. In such a case, the first bank region 11 is transparent to light whose peak wavelength is equal to a green peak wavelength or below. Note that, in the first bank region 11, a region transparent to light whose peak wavelength is equal to the green peak wavelength or below is referred to as a first bank region 11G. Then, the green light L (G) emitted from the green light-emitting layer 6G may be propagated through the first bank region 11G to the red light-emitting layer 6R next to the green light-emitting layer 6G.

### First Modification

As can be seen, in the light-emitting device 1, the first bank region 11B is transparent to light whose peak wavelength is equal to a blue peak wavelength or below. Here, in order to reduce color mixture due to stray light, the first bank region 11B preferably blocks the green light L (G) emitted from the green light-emitting layer 6G and the red light L (R) emitted from the red light-emitting layer 6R, so that neither of lights travels toward the blue light-emitting layer 6B through the first bank region 11B. Hence, in the light-emitting device 1 according to a first modification of the embodiment, the first bank region 11B is a blue color filter.

As can be seen, if the first bank region 11B is the blue color filter, the first bank region 11B can be transparent to the blue light L (B) emitted from the blue light-emitting layer 6B. Hence, the light-emitting device 1 according to the first modification can effectively allow the blue light L (B) to propagate to each of the green light-emitting layer 6G and the red light-emitting layer 6R. Furthermore, the first bank region 11B can absorb the green light L (G) and the red light L (R) traveling from the green light-emitting layer 6G and the red light-emitting layer 6R toward the blue light-emitting layer 6B. Hence, the light-emitting device 1 according to the first modification can keep the green light L (G) and the red light L (R) from entering the blue light-emitting layer 6B. Thus, the light-emitting device 1 according to the first modification can reduce color mixture due to stray light. Note that, if the first bank region 11 is the first bank region 11G, the first bank region 11G is a green color filter.

### Second Modification

In the above light-emitting device 1 according to the embodiment, the third bank region 13 divides the green light-emitting layer 6G from the red light-emitting layer 6R both of which are arranged side-by-side. In contrast, in the light-emitting device 1 according to a second modification of the embodiment, the bank 10, which divides the green light-emitting layer 6G from the red light-emitting layer 6R both of which are arranged side-by-side, also serves as the first bank region 11 (the first bank region 11G).

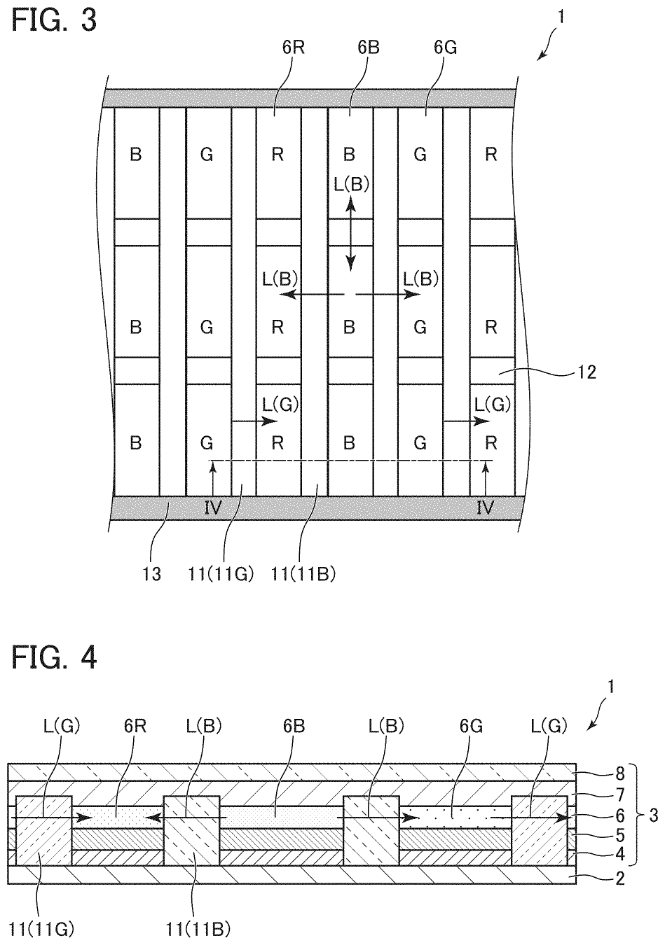

Described below with reference to FIGS. 3 and 4 is the light-emitting device 1 according to the second modification of the embodiment. FIG. 3 is a schematic plan view of an essential configuration of the light-emitting device 1 according to the second modification of the embodiment. FIG. 4 is a cross-sectional view of the light-emitting device 1 illustrated in FIG. 3, taken from line IV-IV of FIG. 3. Note that, in FIGS. 3 and 4, the light L passing through the bank 10 is indicated by arrows. Moreover, in FIG. 3, the blue light-emitting layer 6B, the green light-emitting layer 6G, and the red light-emitting layer 6R are respectively denoted by the signs “B”, “G”, and “R”.

As illustrated in FIGS. 3 and 4, in the light-emitting device 1 according to the second modification of the embodiment, the bank 10 dividing the blue light-emitting layer 6B from the green light-emitting layer 6G both of which are arranged side-by-side, and the bank 10 dividing the blue light-emitting layer 6B from the red light-emitting layer 6R both of which are arranged side-by-side, are the first bank region 11B. Moreover, in the light-emitting device 1 according to the second modification of the embodiment, the first bank region 11G, which is transparent to light whose peak wavelength is equal to a green peak wavelength or below, is the bank 10 dividing the green light-emitting layer 6G from the red light-emitting layer 6R both of which are arranged side-by-side.

The light-emitting device 1 according to the second modification allows the green light-emitting layer 6G and the red light-emitting layer 6R to: absorb a blue light L (B) included in the blue lights L (B) emitted from the blue light-emitting layer 6B and propagating in the in-plane direction of the light emitting surface; and to emit light by photoluminescence (PL). Moreover, the light-emitting device 1 according to the second modification allows the red light-emitting layer 6R to: absorb a green light L (G) included in the green lights L (G) emitted from the green light-emitting layer 6G and propagating in the in-plane direction of the light-emitting surface; and to emit light by PL. Hence, the light-emitting device 1 can further reduce a voltage to be applied to the light-emitting layers 6.

Note that, in the light-emitting device 1 according to the second modification, the first bank region 11B may be a blue color filter, and the first bank region 11G may be a green color filter.

### Third Modification

The light-emitting device 1 according to the above embodiment is configured in such a manner that, of the blue lights L (B) emitted from the blue light-emitting layer 6B, a blue light L (B) propagating in the in-plane direction of the light-emitting surface passes through the first bank region 11B and travels toward each of the green light-emitting layer 6G and the red light-emitting layer 6R both arranged next to the blue light-emitting layer 6B.

In such a configuration, when the blue light L (B) passes through the first bank region 11B and propagates to the green light-emitting layer 6G and the red light-emitting layer 6R, the blue light L (B) spreads out within, and travels through, the first bank region 11B. Hence, some of the blue light L (B) traveling in the in-plane direction of the light-emitting surface might not appropriately enter the green light-emitting layer 6G and the red light-emitting layer 6R.

Hence, in the light-emitting device 1 according to a third modification of the embodiment, an optical waveguide layer 22 is formed in the first bank region 11B to control a region in which the blue light L (B) can propagate.

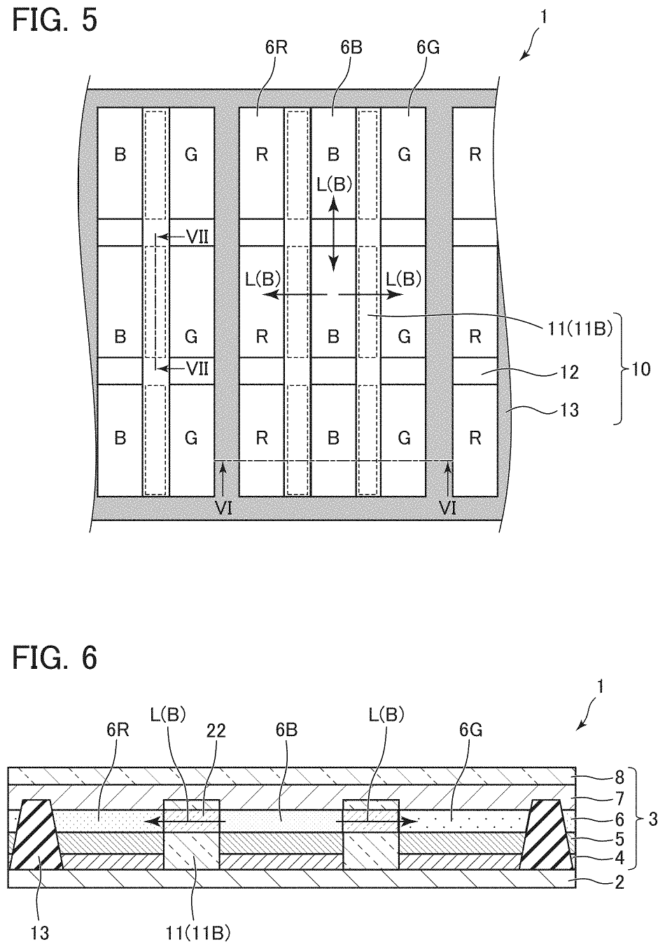

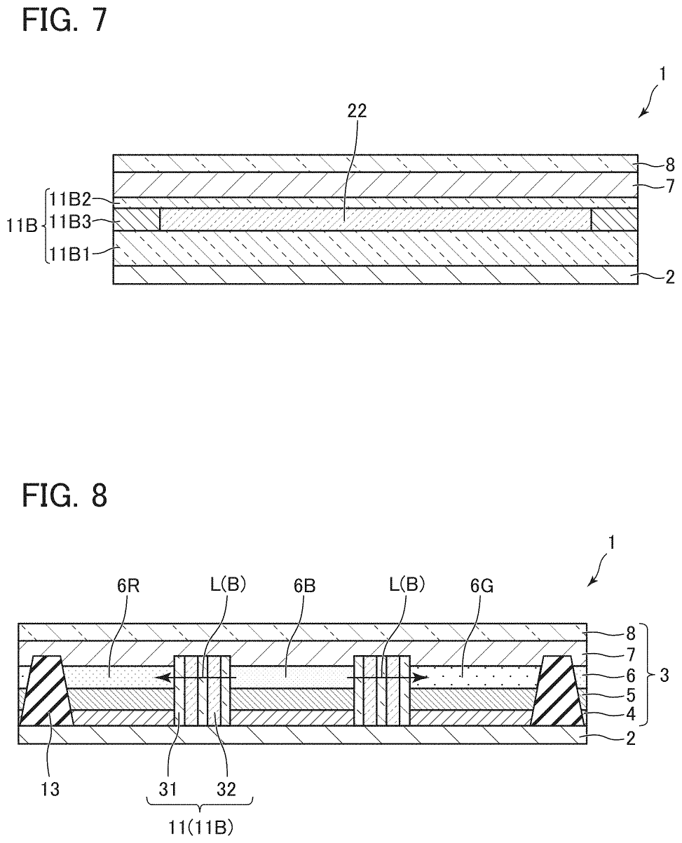

Specifically, as illustrated in FIGS. 5 to 7, the optical waveguide layer 22 is formed in the first bank 11B to connect: the blue light-emitting layer 6B and the green light-emitting layer 6G together; and the blue light-emitting layer 6B and the red light-emitting layer 6R together. FIG. 5 is a schematic plan view of an essential configuration of the light-emitting device 1 according to the third modification of the embodiment. FIG. 6 is a cross-sectional view of the light-emitting device 1 illustrated in FIG. 5, taken from line VI-VI of FIG. 5. FIG. 7 is a cross-sectional view of the light-emitting device 1 illustrated in FIG. 5, taken from line VII-VII of FIG. 5. Note that, in FIGS. 5 and 6, the light L passing through the bank 10 (the first bank region 11) is indicated by arrows.

The optical waveguide layer 22 can be formed in the first bank region 11B as follows. First, on the array substrate 2, a first resin layer 11B1 is stacked to form a base end portion of the first bank region 11B. On the stacked first resin layer 11B1, the optical waveguide layer 22 is stacked. Moreover, on the optical waveguide layer 22, a second resin layer 11B2 is stacked to form a distal end portion of the first bank region 11B. Hence, the first bank region 11B includes the first resin layer 11B1 and the second resin layer 11B2 stacked to hold the optical waveguide layer 22. Next, exposed portions of opposing end portions (horizontal end portions in FIG. 7) of the optical waveguide layer 22 are covered with a cover portion 11B3. Then, the first resin layer 11B1, the second resin layer 11B2, the cover portion 11B3, and the optical waveguide layer 22 are patterned to form the first bank region 11B in a desired shape.

In the light-emitting device 1 according to the third modification of the embodiment, the blue light L (B) emitted from the blue light-emitting layer 6B is efficiently propagated through the optical waveguide layer 22 to the green light-emitting layer 6G and the red light-emitting layer 6R arranged next to the blue light-emitting layer 6B. Hence, in the light-emitting device 1 according to the third modification of the embodiment, the light-emitting layer 6 and the optical waveguide layer 22 are configured to satisfy the condition below.

That is, in order to form a waveguide mode in the blue light-emitting layer 6B, a refractive index of the blue light-emitting layer 6B is set greater than a refractive index of a first neighboring layer (the hole-transport layer 5 and the electron-transport layer 7) staked next to the blue light-emitting layer 6B. Specifically, the refractive index of the blue light-emitting layer 6B is set greater by 0.3% or more than the refractive index of each of the hole-transport layer 5 and the electron-transport layer 7 staked next to the blue light-emitting layer 6B. This set value (0.3% or more) is a value obtained as a refractive index difference required to allow the light to be totally reflected on an interface between the blue light-emitting layer 6B and the first neighboring layer (the hole-transport layer 5 and the electron-transport layer 7). Note that the waveguide mode here is a mode of the light propagating inside the optical waveguide 22 while the light is totally reflected on an interface between the optical waveguide 22 and a member (a layer) of the first bank region 11 surrounding the optical waveguide 22.

Moreover, when the blue light L (B) propagates in the in-plane direction of the light-emitting surface, the amount of the blue light L (B) confined in the blue light-emitting layer 6B depends on a thickness of the blue light-emitting layer 6B. Hence, as a condition to form the waveguide mode, a product of the thickness and the refractive index of the blue light-emitting layer 6B is set greater than a half wavelength of the emitted blue light L (B).

Moreover, in order to form the waveguide mode in the optical waveguide layer 22, the refractive index of the optical waveguide layer 22 is set greater in the first bank region 11B than a refractive index of a member surrounding an outer periphery of the optical waveguide layer 22. In this Description, the member to surround the outer periphery of the optical waveguide layer 22 includes the first resin layer 11B1, the second resin layer 11B2, and the cover portion 11B3 illustrated in FIG. 7. The optical waveguide layer 22 can be formed of, for example, TiO₂, Nb₂O₅, Ta₂O₅, SiO₂, MgF₂, and Al₂O₃. Moreover, the first resin layer 11B1 and the second resin layer 11B2 can be formed of, for example, acrylic polymer, polysiloxane, and polyimide. The cover portion 11B3 can be formed of, for example, acrylic polymer, polysiloxane, and polyimide. Note that, in this Description, the first resin layer 11B1, the second resin layer 11B2, and the cover portion 11B3 may collectively be referred to as a second neighboring layer. Specifically, the refractive index of the optical waveguide layer 22 is set greater by 0.3% or more than the refractive index of each of the first resin layer 11B1 and the second resin layer 11B2 included in the first bank region 11B and stacked on top of another next to the optical waveguide layer 22. Moreover, the refractive index of the optical waveguide layer 22 is set higher by 0.3% or more than the refractive index of the cover portion 11B3 in the first bank region 11B. This set value (0.3% or more) is a value obtained as a refractive index difference required to cause the light to be totally reflected on an interface between the optical waveguide 22 and the second neighboring layer (the first resin layer 11B1, the second resin layer 11B2, and the cover portion 11B3). Moreover, the amount of the light confined in the optical waveguide layer 22 depends on a thickness of the optical waveguide layer 22. Hence, a product of the thickness and the refractive index of the optical waveguide layer 22 is set greater than a half wavelength of the propagating blue light L (B). Note that the optical waveguide layer 22 can be formed of, at least one of TiO₂, Nb₂O₅, Ta₂O₅, SiO₂, MgF₂, or Al₂O₃.

Furthermore, the optical waveguide layer 22 and the light-emitting layer 6 (the blue light-emitting layer 6B, the green light-emitting layer 6G, or the red light-emitting layer 6R) are provided so that a level difference between the upper faces of, and between the lower faces of, the layers is 0.3 nm or less. As can be seen, when the level difference of 0.3 nm or less is set between the optical waveguide layer 22 and the light-emitting layer 7, scattering of light is successfully prevented on the interface between the optical waveguide layer 22 and the light-emitting layer 6. Thus, the scattering of light is successfully prevented, thereby making it possible to reduce leakage of light and the resulting loss of the light to be absorbed into the light-emitting layer 6. Note that, in order to set the level difference to 0.3 nm or less between the optical waveguide layer 22 and the light-emitting layer 6, an exemplary processing to planarize the layers is either the plasma processing or the CMP processing.

Moreover, in order to reduce reflection of light on the interface between the optical waveguide layer 22 and the light-emitting layer 6, the optical waveguide layer 22 and the light-emitting layer 6 preferably have the same refractive index.

Furthermore, in the light-emitting device 1 according to the third modification of the embodiment, microtexturing is provided on the interface between the light-emitting layer 6 (for example, the blue light-emitting layer 6B in FIG. 6) and the optical waveguide layer 22. Such a feature can reduce reflection of light on the interface between the light-emitting layer 6 and the optical waveguide layer 22.

### Fourth Modification

In the light-emitting device 1 according to the above embodiment, the first bank region 11B is transparent to light whose peak wavelength is equal to the blue peak wavelength or below. Here, in view of reducing color mixture and loss of light, the first bank region 11B is particularly preferably transparent to light having a blue peak wavelength and reflective to other light.

Hence, in the light-emitting device 1 according to a fourth modification of the embodiment, as illustrated in FIG. 8, the first bank region 11B is a dielectric multilayer film. FIG. 8 is a cross-sectional view of an essential configuration of the light-emitting device 1 according to the fourth modification of the embodiment. FIG. 8, which is similar to FIG. 2, is a cross-sectional view of the light-emitting device 1, taken from line II-II of FIG. 1. Note that, in FIG. 8, the light L passing through the bank 10 (the first bank region 11) is indicated by arrows.

The dielectric multilayer film is a multilayer stack of optical thin films made of a plurality of dielectric materials having different refractive indexes. As to the dielectric multilayer film, the thicknesses and materials of the optical thin films are appropriately set so that the dielectric multilayer film can be transparent only to a light ray having a specific peak wavelength and reflective to light rays having other peak wavelengths. Hence, in the light-emitting device 1 according to the fourth modification, the dielectric multilayer film is reflective to the red light L (R) and the green light L (G), and transparent to the blue light L (B).

Specifically, the dielectric multilayer film included in the first bank region 11B according to the fourth modification is a multilayer stack including a combination of two or more layers including a high refractive index layer 31 (a first refractive index layer) and a low refractive index layer 32 (a second refractive index layer). That is, the multilayer film contains. TiO₂ (a thickness of 185 nm) as the high refractive index layer 31; and MgF₂ (a thickness of 295 nm) as the low refractive index layer 32. Then, the dielectric multilayer film is formed of the high refractive index layer 31 and the low refractive index layer 32 stacked together. In FIG. 8, for the sake of description, the illustrated dielectric multilayer film is formed of five layers in total including three high refractive index layers 31 and two low refractive index layers 32. However, the dielectric multilayer film shall not be limited to such a configuration. The dielectric multilayer film is formed of a combination of two layers including at least the high refractive index layer 31 and the low refractive index layer 32. Particularly preferably, for the dielectric multilayer film, TiO₂ (a thickness of 185 nm) is selected as the high refractive index layer 31 and MgF₂ (a thickness of 295 nm) is selected as the low refractive index layer 32. Eleven or more of low refractive index layers 32 and high refractive index layers 31 are alternately stacked together to form the dielectric multilayer film.

Note that the above high refractive index layer 31 is formed of TiO₂. However, the high refractive index layer 31 may be formed of Nb₂O₅ or Ta₂O. Moreover, the above low refractive index layer 32 is formed of MgF₂. However, the low refractive index layer 32 may be formed of SiO₂ or Al₂O₃.

As can be seen, if the first bank region 11B is a dielectric multilayer film, the first bank region 11B is previously formed on a separate substrate by such a technique as the CVD. Then, the first bank region 11B formed on this separate substrate is stacked in an appropriate position on the array substrate 2 by reprinting or manipulation.

Note that the features of the above embodiment and modifications may appropriately be combined together.

### REFERENCE SIGNS LIST

1 Light-Emitting Device
2 Array Substrate
3 Light-Emitting Element
6 Light-Emitting Layer
6B Blue Light-Emitting Layer
6G Green Light-Emitting Layer
6R Red Light-Emitting Layer
10 Bank
11 First Bank Region
11B First Bank Region
11G First Bank Region
11B1 High Refractive Index Layer
11B2 Low Refractive Index Layer
12 Second Bank Region
13 Third Bank Region
22 Optical Waveguide Layer

1. A light-emitting element, comprising:
a first light-emitting layer containing first quantum dots and configured to emit a first light including a first peak wavelength;
a second light-emitting layer containing second quantum dots and configured to emit a second light including a second peak wavelength greater than the first peak wavelength;
a substrate having a surface on which the first light-emitting layer and the second light-emitting layer are arranged side-by-side in a first direction; and
a first bank provided on the substrate and dividing the first light-emitting layer from the second light-emitting layer,
wherein the first bank is transparent to the first light traveling from the first light-emitting layer toward the second light-emitting layer.

2. The light-emitting element according to claim 1,
wherein the first bank includes a color filter transparent to the first light and absorptive of the second light.

3. The light-emitting element according to claim 1,
wherein the first light-emitting layer and the first bank are formed to satisfy a relationship of:
n_{QD}×9/11<n<n_{QD}×11/9,
where n_{QD} is a refractive index of the first light-emitting layer, and n is a refractive index of the first bank.

4. The light-emitting element according to claim 1,
wherein the first bank has an optical waveguide layer provided between the first light-emitting layer and the second light-emitting layer and guiding the first light.

5. The light-emitting element according to claim 4,
wherein a refractive index of the optical waveguide layer is higher than a refractive index of a member surrounding an outer periphery of the optical waveguide layer.

6. The light-emitting element according to claim 1,
wherein the first bank includes a dielectric multilayer film transparent to the first light and reflective to the second light.

7. The light-emitting element according to claim 6,
wherein the dielectric multilayer film is a multilayer stack including a combination of two or more layers including a first refractive index layer and a second refractive index layer, the first refractive index layer being a dielectric film having a first refractive index and the second refractive index layer being a dielectric film having a second refractive index lower than the first refractive index.

8. The light-emitting element according to claim 7,
wherein the first refractive index layer contains at least one of TiO₂, Nb₂O₅, or Ta₂O₅, and
the second refractive index layer contains at least one of SiO₂, MgF₂, or Al₂O₃.

9. The light-emitting element according to claim 1,
wherein, on the surface of the substrate, a plurality of the first light-emitting layers are arranged in a second direction different from the first direction,
the light-emitting element further comprises a second bank dividing the plurality of first light-emitting layers arranged side-by-side, and
the second bank is transparent to the first light incident to each of the first light-emitting layers arranged side-by-side.

10. A light-emitting element, comprising:
a plurality of first light-emitting layers each containing first quantum dots and configured to emit a first light including a first peak wavelength;
a substrate on which the plurality of first light-emitting layers are arranged in line; and
a bank provided on the substrate and dividing two of the first light-emitting layers arranged side-by-side,
wherein, between the two first light-emitting layers, the bank is transparent to the first light emitted from each of the two first light-emitting layers.

11. The light-emitting element according to claim 10,
wherein the bank contains at least one resin selected from the group consisting of acrylic polymer, polysiloxane, and polyimide.

12. A light-emitting device, comprising:
a thin-film transistor; and
the light-emitting element according to claim 1, the light-emitting element being electrically connected to the thin-film transistor.
